(19) United States
(12) Patent Application Publication
(10) Pub. No.: US 2023/0402393 A1
(43) Pub. Date: Dec. 14, 2023

(54) ELECTRONIC DEVICE AND MANUFACTURING METHOD THEREOF

(71) Applicant: InnoLux Corporation, Miao-Li County (TW)

(72) Inventors: Cheng-Chi WANG, Miao-Li County (TW); Chin-Ming HUANG, Miao-Li County (TW); Chia-Lin YANG, Miao-Li County (TW)

(21) Appl. No.: 17/819,117

(22) Filed: Aug. 11, 2022

(30) Foreign Application Priority Data
Jun. 14, 2022 (CN) 202210667709.1

(51) Int. Cl. H01L 23/538; H01L 21/82; H01L 21/469

(52) U.S. Cl. CPC H01L 23/5389; H01L 23/5386; H01L 21/82; H01L 21/469

(57) ABSTRACT

An electronic device is provided. The electronic device includes an electronic unit, a protective layer, and a circuit layer. The electronic unit includes a chip unit, a first insulating layer, and a second insulating layer. The first insulating layer is disposed on the chip unit, and the second insulating layer is disposed on the first insulating layer. The second insulating layer has a first side. The first side overlaps the chip unit along the normal direction of the electronic unit. The protective layer surrounds the electronic unit, and the circuit layer electrically connects the electronic unit.

### CROSS REFERENCE TO RELATED APPLICATIONS

This application claims priority of China Patent Application No. 202210667709.1, filed on Jun. 14, 2022, the entirety of which is incorporated by reference herein.

### BACKGROUND

### Technical Field

The disclosure relates to an electronic device and a manufacturing method thereof, and in particular, to an electronic device with multiple insulating layers and a manufacturing method thereof.

### Description of the Related Art

As consumers prefer thinner and lighter electronic products, related electronic devices tend to be miniaturized. Therefore, it is an urgent need to propose a method for manufacturing an electronic device with reduced size, improved performance, and lower cost.

For example, fan-out package technology is currently a much more advanced package technology. Although the chip size continues to be scaled down, fan-out package technology may provide a highly integrated package structure by extending the wiring in a fan-out manner from the area where the die is configured. Fan-out package technology has attracted attention due to its high potential for development. However, many challenges still remain in the manufacturing process with fan-out package technology. Accordingly, various solutions to bottlenecks in the manufacturing process are still needed, to improve the reliability and yield of electronic devices.

### BRIEF SUMMARY OF THE DISCLOSURE

An electronic device is provided according to some embodiments of the disclosure. The electronic device includes an electronic unit, a protective layer, and a circuit layer. The electronic unit includes a chip unit, a first insulating layer, and a second insulating layer. The first insulating layer is disposed on the chip unit, and the second insulating layer is disposed on the first insulating layer. The second insulating layer has a first side. The first side overlaps the chip unit along the normal direction of the electronic unit. The protective layer surrounds the electronic unit, and the circuit layer electrically connects the electronic unit.

A method for manufacturing an electronic device is provided according to some embodiments of the disclosure. The method includes: providing a chip unit; forming a first insulating layer on the chip unit; forming a second insulating layer on the first insulating layer; and performing a dicing process to form an electronic unit. The second insulating layer has a first side that overlaps the electronic unit along a normal direction of the electronic unit after the dicing process.

The features and the advantages of the disclosure may be more fully understood by reading the subsequent detailed description and examples with references made to the accompanying drawings.

### BRIEF DESCRIPTION OF THE DRAWINGS

FIGS. 1 and 2A illustrate cross-sectional views of an electronic device at various intermediate stages of its manufacturing process according to some embodiments of the disclosure.

FIG. 2B illustrates an enlarged local side view of an electronic device according to some embodiments of the disclosure.

FIGS. 3-11 illustrate cross-sectional views of an electronic device at various intermediate stages of its manufacturing process according to some embodiments of the disclosure.

### DETAILED DESCRIPTION OF THE DISCLOSURE

The electronic device and the manufacturing method thereof provided in the disclosure are described in detail in the following description. It should be appreciated that the following disclosure provides many different embodiments, or examples, for implementing different features of the disclosure. Specific examples of elements and arrangements are described below to clearly describe the disclosure in a simple manner. These are, of course, merely examples and are not intended to be limiting. In addition, different embodiments may use like and/or corresponding reference numerals to denote like and/or corresponding elements for clarity. However, like and/or corresponding reference numerals are used merely for the purpose of clarity and simplicity, and do not suggest any correlation between different embodiments.

It should be appreciated that the drawings of the disclosure are not drawn to scale. In fact, the dimensions of the various elements may be arbitrarily increased or reduced for clarity of the features of the disclosure.

In addition, the expression “a layer is disposed above another layer” or “a layer is disposed on another layer” may indicate that the layer is in direct contact with the other layer, or that the layer is not in direct contact with the other layer, there being one or more intermediate layers disposed between the layer and the other layer.

It should be understood that, in the specification and the appended claims, the ordinal numbers like “first” and “second” are just descriptive of the elements following them and do not mean or signify that the elements are so numbered, that one claimed element is arranged with another claimed element in that order, or that the claimed elements are produced in that order. These ordinal numbers are only used to differentiate one claimed element having a denomination from another claimed element having the same denomination. The same denomination may not be used in the specification and the appended claims. For example, the first element in the specification may be the second element in the appended claims.

The terms “about” typically means+/−10% of the stated value, or typically means+/−5% of the stated value, or typically means+/−3% of the stated value, or typically means+/−2% of the stated value, or typically means+/−1% of the stated value, or typically means+/−0.5% of the stated value. The stated value of the disclosure is an approximate value. When there is no specific description, the stated value includes the meaning of “about”. In addition, the expression “greater than or equal to the first value and less than or equal to the second value” indicates that the range described includes the first value, the second value, and other values therebetween.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the disclosure and the background or the context of the disclosure, and should not be interpreted in an idealized or overly formal manner unless so defined.

In accordance with the embodiments of the disclosure, an optical microscopy (OM), a scanning electron microscope (SEM), a film thickness profiler (α-step), an ellipsometer or other suitable methods may be used to measure the spacing or distance between elements, or the width, thickness, height, or area of each element. In particular, in accordance with some embodiments, a scanning electron microscope may be used to obtain any cross-sectional image including the elements to be measured, and the spacing or distance between elements, or the width, thickness, height, or area of each element in the image may be measured.

It should be understood that the following embodiments can be substituted, reorganized, and mixed to complete other embodiments without departing from the spirit of the present disclosure. As long as the features of the embodiments do not violate the spirit of the invention or conflict, they can be mixed and matched arbitrarily.

It should be understood that the electronic device of the disclosure may include a package device, a package module, a display device, an antenna device, a touch display device, a radar device, a light detection and ranging (LiDAR) device, a curved display device, or a non-rectangular electronic device (free shape display), but the disclosure is not limited thereto. The electronic device can be a bendable or flexible electronic device. The electronic device may, for example, include light-emitting diodes, liquid crystals, fluorescence, phosphors, other suitable display media, or combinations thereof, but the disclosure is not limited thereto. The light-emitting diodes may include, for example, organic light-emitting diodes (OLEDs), inorganic light-emitting diodes, sub-millimeter light-emitting diodes (sub-mini LEDs), and micro-light-emitting diodes (micro-LED), quantum dots light-emitting diodes (e.g., QLED or QDLED), another suitable material, or a combination thereof, but the disclosure is not limited thereto.

For example, the system-in-package (SiP) technique or the system-on-chip (SoC) technique may be adopted for the package device. In addition, the wafer-level package (WLP) technique or panel-level package (PLP) technique, which includes a chip-first process or a redistribution layer first (RDL-first) process, may be used to form the package device.

The display device may include, for example, a splicing display device, but the disclosure is not limited thereto. The concept or principle of the disclosure may also be applied to a non-emissive liquid crystal display (LCD), but the disclosure is not limited thereto.

The antenna device may include, for example, a liquid crystal antenna or other types of antennas, but the disclosure is not limited thereto. The antenna device may include, for example, an antenna splicing device, but the disclosure is not limited thereto. It should be noted that the electronic device can be any combination of the foregoing, but the disclosure is not limited thereto. In addition, shape of the electronic device may be rectangular, circular, polygonal, a shape with curved edges, or other suitable shapes. The electronic device may have peripheral systems such as a driving system, a control system, a light source system, a rack system, etc., to support a display device, an antenna device, or a splicing device. For example, the electronic device of the disclosure may be a display device, but the disclosure is not limited thereto.

In some embodiments of the disclosure, unless defined otherwise, the terms “connect”, “interconnect”, and the like with regard to bonding or connecting may mean that two structures are in direct contact, or that other structures are disposed between them such that they may not be in direct contact. The terms with regard to bonding or connecting may also include the circumstances in which two structure are both movable or fixed. Furthermore, the term “electrically connected’ or “electrically coupled” includes any direct or indirect means for electrical connection.

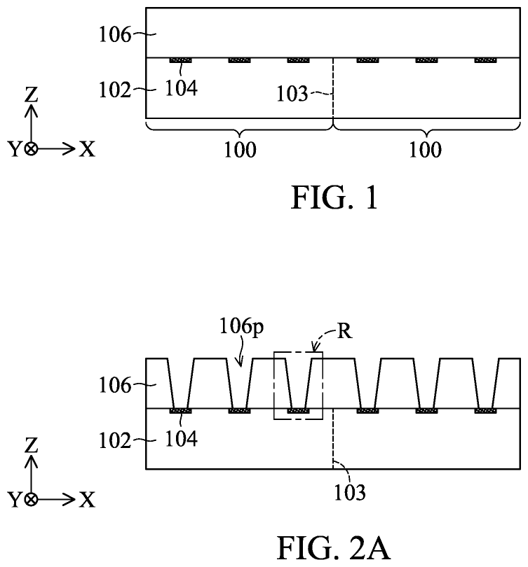

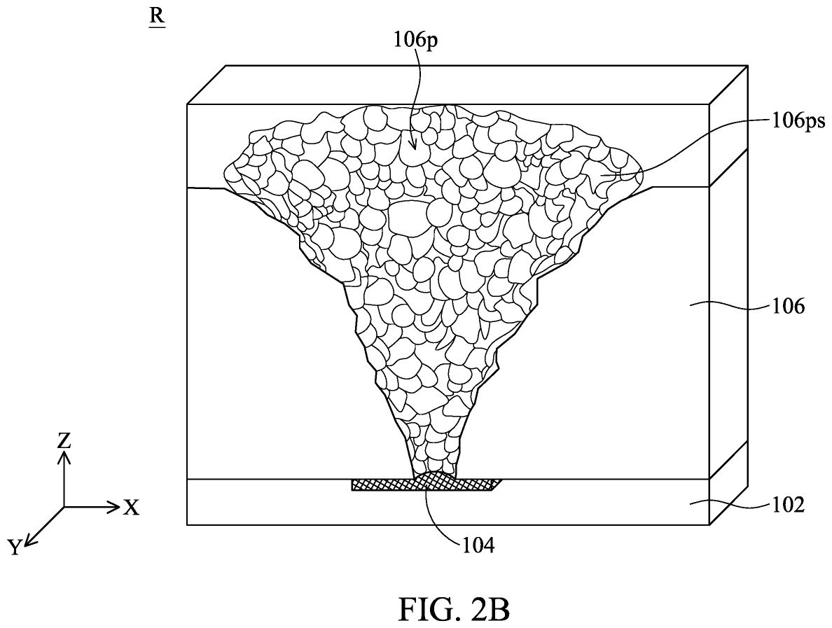

FIGS. 1 and 2A illustrate cross-sectional views of an electronic device at various intermediate stages of its manufacturing process according to some embodiments of the disclosure, and FIG. 2B illustrates an enlarged local side view of an electronic device according to some embodiments of the disclosure. Referring to FIG. 1, chip units 102 are provided. Each chip unit 102 is included in an electronic unit 100. It should be noted that the chip units 102 in FIG. 1 remain undiced. Therefore, individual chip units 102 are separated by a dashed line 103, and a dicing process will be used in the subsequent processes to separate the chip units 102 and subsequently formed features of each electronic unit 100.

In some embodiments, the chip unit 102 may be a known good die. For example, the chip unit 102 may include a low noise amplifier (LNA), a low-loss filter, a power amplifier, a baseband circuit, a power management integrated circuit (PMIC), a memory, a micro electro mechanical system (MEMS) device, an integrated circuit, another suitable active or passive component, diodes, or a combination thereof, but the disclosure is not limited thereto.

According to some embodiments, the electronic unit 100 may further include conductive pads 104. In some embodiments, as shown in FIG. 1, the conductive pads 104 may be disposed on the upper surface of the chip unit 102. In some embodiments, the material of the conductive pads 104 may include, but is not limited to, Al, Cu, Mo, Ti, Pt, Ir, Ni, Cr, Ag, Au, W, or an alloy thereof.

Next, referring again to FIG. 1, a first insulating layer 106 is formed on the chip units 102. In some embodiments, the first insulating layer 106 may cover the chip units 102 and the conductive pads 104. According to some embodiments, the first insulating layer 106 may be in direct contact with the conductive pads 104. According to some embodiments, the material of the first insulating layer 106 may include an organic material, an inorganic material, an organic-inorganic composite material, or a combination thereof. For example, the organic material may include epoxy, polyimide (PI), siloxane, an Ajinomoto build-up film (ABF), another suitable organic material, or a combination thereof, but the disclosure is not limited thereto. For example, the inorganic material may include silicon oxide, silicon nitride, silicon oxynitride, phosphosilicate glass (PSG), borophosphosilicate glass (BPSG), a low-k dielectric material, another suitable dielectric material, or a combination thereof, but the disclosure is not limited thereto. In some embodiments, the low-k dielectric material may include, but is not limited to, fluorinated silica glass (FSG), carbon doped silicon oxide, amorphous fluorinated carbon, another suitable low-k dielectric material, or a combination thereof.

In other embodiments, the material of the first insulating layer 106 may include an Ajinomoto build-up film (ABF), photosensitive polyimide (PSPI), or a combination thereof, but the disclosure is not limited thereto. According to some embodiments, the material of the first insulating layer 106 may further include fillers, such as dielectric fillers, metallic fillers, or a combination thereof. For example, the dielectric fillers may include, but are not limited to, silicon oxide, silicon nitride, titanium dioxide, zirconium oxide, aluminum oxide, magnesium oxide, aluminum nitride, boron nitride, diamond powder, or a combination thereof. For example, the metallic fillers may include, but are not limited to, silver, copper, aluminum, or a combination thereof. In the embodiments in which the first insulating layer 106 further includes fillers, the fillers may enhance structural strength of the first insulating layer 106, providing stable protection for the underlying chip units 102 during the following processes so that the chip units 102 may not be damaged.

Next, referring to FIG. 2A, in some embodiments, openings 106p are formed in the first insulating layer 106. Each opening 106p may expose the conductive pad 104 of the electronic unit 100 to form electric connection. In some embodiments, a laser drilling process or a patterning process may be used to form the openings 106p in the first insulating layer 106. The patterning process may include a photolithography process and an etching process. In some embodiments, the photolithography process may include photoresist coating, pre-baking, mask aligning, exposure, post-exposure baking (PEB), developing the photoresist, rinsing, drying, or other suitable processes. In some embodiments, the etching process may include a dry etching process, a wet etching process, or a combination thereof. For example, the dry etching process may include a reactive ion etching (RIE) process, inductively coupled plasma reactive ion etching (ICP-RIE), a plasma etching process, or a combination thereof. In one embodiment, the laser drilling process is used to form the openings 106p in the first insulating layer 106.

Referring to FIG. 2B, FIG. 2B is an enlarged local side view of a region R in FIG. 2A. According to some embodiments, although the openings 106p have tapered sidewalls in FIG. 2A and the following figures, the openings 106 may have a concave shape or a bowl-shape structure as shown in FIG. 2B. Furthermore, in some embodiments, although the surface profile of sidewalls 106ps of the openings 106p are not explicitly illustrated in FIG. 2A, the sidewalls 106ps of the openings 106 may have uneven surfaces because the material of the first insulating layer 106 further includes fillers that can enhance structural strength.

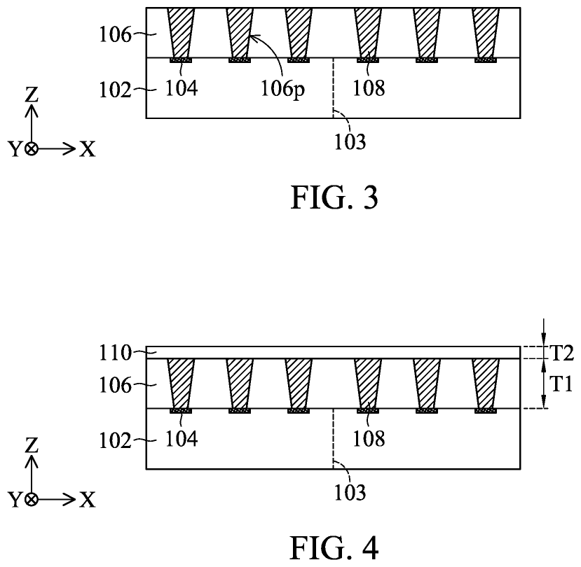

FIGS. 3-6 illustrate cross-sectional views of an electronic device at various intermediate stages of its manufacturing process according to some embodiments of the disclosure. Referring to FIG. 3, a first metal layer 108 is filled in the openings 106p. The material of the first metal layer 108 may include, but is not limited to, Aluminum (Al), Copper (Cu), Tungsten (W), Titanium (Ti), Tantalum (Ta), Nickel (Ni), Titanium Nitride (TiN), Tantalum Nitride (TaN), Nickel Silicide (NiSi), Cobalt silicide (CoSi), tantalum carbide (TaC), tantalum silicon nitride (TaSiN), tantalum carbonitride (TaCN), titanium aluminum nitride (TiAl), titanium aluminum nitride (TiAlN), another suitable conductive material, or a combination thereof. The material of the first metal layer 108 may be formed using physical vapor deposition (PVD), atomic layer deposition (ALD), metalorganic chemical vapor deposition (MOCVD), an electroplating process, another suitable processing technique, or a combination thereof.

As shown in FIG. 3, in some embodiments, after the formation of the first metal layer 108, a planarization process, such as mechanical polishing or chemical mechanical polishing (CMP), may be performed on the first insulating layer 106 and the first metal layer 108 so that the first insulating layer 106 and the first metal layer 108 may have substantially level upper surfaces, but the disclosure is not limited thereto.

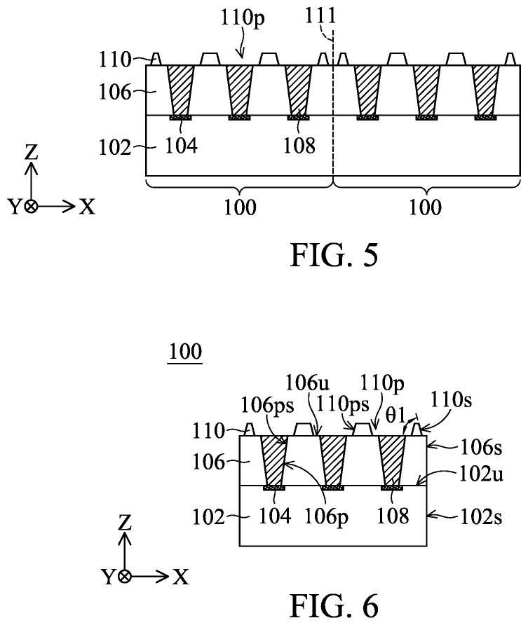

Next, referring to FIGS. 4-6, a second insulating layer 110 is formed on the first insulating layer 106. Subsequently, according to some embodiments, openings 110p are formed in the second insulating layer 110. In some embodiments, as shown in FIGS. 5 and 6, the openings 110p may expose the first metal layer 108 and a portion of the upper surface 106u of the first insulating layer 106. In some embodiments, the material of the second insulating layer 110 may include an organic polymer material. In some embodiments, the material of the second insulating layer 110 may include photoresist. According to some embodiments, when the material of the second insulating layer 110 includes photoresist, a photolithography process may be used to remove a portion of the second insulating layer 110 to form the openings 110p.

Moreover, in one embodiment, as shown in FIG. 5, a predetermined dicing lane 111 may be present between neighboring electronic units 100, and a portion of the second insulating layer 110 that is located at the dicing lane 111 may be removed to expose the location to be diced of the electronic units 100. In some embodiments, after the formation of the openings 110p, a suitable dicing process is performed on the structure shown in FIG. 5 to separate neighboring electronic units 100. In particular, the electronic units are diced at the dicing lane 111 to separate neighboring electronic units 100. For example, the suitable dicing method may include etching, cutting wheel dicing, laser dicing, another suitable dicing technique, or a combination thereof.

As shown in FIG. 6, in the electronic unit 100 after the dicing process, the side 110s of the second insulating layer 110 overlaps the chip unit 102 along the normal direction of the electronic unit 100 (e.g., the Z direction in FIG. 6). More specifically, in some embodiments, the projection plane of the side 110s of the second insulating layer 110 on the chip unit 102 falls within the upper surface 102u of the chip unit 102. In addition, in some embodiments, the side 110s of the second insulating layer 110 may gradually taper along the direction away from the chip unit 102. According to some embodiments, the angle θ1 between the side 110s and the lower surface of the second insulating layer 110 may be greater than or equal to about 45° and less than about 90°, such as about 55°, 77.5°, or 80°, but the disclosure is not limited thereto. In some embodiments, the first insulating layer 106 may be exposed in the region outside the side 110s of the second insulating layer 110. With the angle θ1 greater than or equal to 45° and less than 90°, the adhesion of the second insulating layer 110 to the surface of the first insulating layer 106 may be enhanced, but the disclosure is not limited thereto.

Furthermore, as shown in FIG. 6, in some embodiments, after the dicing process, the side 102s of the chip unit 102 may be aligned with the side 106s of the first insulating layer 106. The term “aligned with” used herein means that, in a direction (e.g., the X direction in FIG. 6) perpendicular to the normal direction of the chip unit (e.g., the Z direction in FIG. 6), if the distance between sides of two elements (e.g., the chip unit 102 and the first insulating layer 106) is less than about 5 μm, these elements are considered to be aligned with each other. The extension direction of the side 102s of the chip unit 102 and the side 106s of the first insulating layer 106 may substantially parallel the normal direction of the chip unit 102 (e.g., the Z direction in FIG. 6).

In some embodiments, the roughness of the side 106s of the first insulating layer 106 may be different from that of the side 102s of the chip unit 102. In one embodiment, the roughness of the side 106s of the first insulating layer 106 may be greater than that of the side 102s of the chip unit 102. In the embodiments in which the material of the first insulating layer 106 further includes fillers, since the fillers are included in the first insulating layer 106, the roughness of the side 106s of the first insulating layer 106 after the dicing process may be greater than that of the side 102s of the chip unit 102. According to some embodiments, the roughness of the side 106s of the first insulating layer 106 may be between about 2.0 μm and about 12.0 m, such as about 7.0 μm, and the roughness of the side 102s of the chip unit 102 may be between about 0.05 μm and about 0.25 μm, such as about 0.15 μm.

Moreover, in some embodiments, the roughness of the sidewall 110ps of the opening 110p in the second insulating layer 110 may be different from that of the sidewall 106ps of the opening 106p in the first insulating layer 106. In one embodiment, the roughness of the sidewall 106ps of the opening 106p in the first insulating layer 106 may be greater than that of the sidewall 110ps of the opening 110p in the second insulating layer 110. According to some embodiments, the roughness of the sidewall 106ps of the opening 106p in the first insulating layer 106 may be between about 2.0 μm and about 12.0 μm, such as about 7.0 μm, and the roughness of the sidewall 110ps of the opening 110p in the second insulating layer 110 may be between about 0.5 μm and about 1.5 μm, such as about 0.9 μm. The first insulating layer 106 with higher roughness may enhance adhesion of metal layers, insulating layers, or other elements to the chip unit.

It should be noted that the term “roughness” used herein refers to the degree to which the surface of an object fluctuates. Specifically, the “roughness” value of a surface or a sidewall may be obtained according to the average roughness (Rz) of ten sampling points. The average roughness (Rz) of ten sampling points is defined as the sum of the average absolute values of five maximum peaks and the average absolute values of five minimum valleys. These five maximum peaks and five minimum valleys are obtained within a length to be evaluated. In particular, the average roughness (Rz) of ten sampling points is calculated using the following equation:

$${R}_{z} = \frac{1}{5} {\sum }_{i = 1}^{5} {R}_{pi -} {R}_{vi} ,$$

in which Rₚᵢ and Rᵥᵢ are the i^{th} peak value and the i^{th} valley value, respectively. In some embodiments, the term “roughness” as used herein refers to average roughness. The roughness can be measured using any common instruments used in the art. For example, a focus ion beam microscope, a scanning electron microscope, or a transmission electron microscope with a magnification of 5,000× to 50,000×, or an atomic force microscope, which can measure a sample with dimensions of 10 μm to 100 μm, can be used to measure the average roughness of a surface.

According to some embodiments, the first insulating layer 106 and the second insulating layer 110 may have different stiffness. The term “stiffness” as used herein refers to the extent to which a material is deformed by external forces. Any conditions that may cause the devices of the disclosure to deform may belong to the external forces indicated in the disclosure. Generally, the stiffness of the first insulating layer 106 and the second insulating layer 110 may be determined by several indices, such as thickness, coefficient of thermal expansion (CTE), Young's modulus, another suitable index, or a combination thereof, which will be described in detail below.

In particular, in one embodiment, the stiffness of the first insulating layer 106 may be greater than that of the second insulating layer 110. For example, in some embodiments, as shown in FIG. 4, along the Z direction (e.g., the normal direction of the chip unit 102), the thickness T1 of the first insulating layer 106 may be different from the thickness T2 of the second insulating layer 110. In one embodiment, the thickness T1 of the first insulating layer 106 may be greater than the thickness T2 of the second insulating layer 110. According to some embodiments, the thickness T1 of the first insulating layer 106 may be between about 13 μm and about 50 μm, such as about 30 μm, and the thickness T2 of the second insulating layer 110 may be between about 2 μm and about 10 μm, such as about 6 μm. In addition, in some embodiments, the CTE of the first insulating layer 106 may be different from the CTE of the second insulating layer 110. In one embodiment, the CTE of the first insulating layer 106 may be less than the CTE of the second insulating layer 110. In some embodiments, the CTE of the first insulating layer 106 may be between about 3.0×10⁻⁶/° C. and about 12×10⁻⁶/° C., and the CTE of the second insulating layer 110 may be between about 15×10⁻⁶/° C. and about 40×10⁻⁶/° C. Furthermore, according to some embodiments, the Young's modulus of the first insulating layer 106 may be different from that of the second insulating layer 110. In one embodiment, the Young's modulus of the first insulating layer 106 may be less than that of the second insulating layer 110. According to some embodiments, the Young's modulus of the first insulating layer 106 may be between about 4.3 GPa and about 20 GPa, and the Young's modulus of the second insulating layer 110 may be between about 1.0 GPa and about 4.0 GPa.

According to some embodiments, the CTEs of the first insulating layer 106 and the second insulating layer 110 may be measured using a dilatometer, but the CTE measuring method is not limited thereto. Alternatively, the CTE may also be obtained using a table lookup method in which a specific CTE may correspond to a specific material. According to some embodiments, the Young's modulus described in the disclosure may be measured using a universal testing machine, but the method of measuring the Young's modulus is not limited thereto. For example, a universal testing machine may be used to obtain the relationship between the deformation of the first insulating layer 106 or the second insulating layer 110 and the load, and the Young's modulus may be calculated accordingly. A first insulating layer or a second insulating layer (e.g., 40 mm×40 mm×1 mm) is placed on the universal testing machine, and the crosshead of the universal testing machine presses the sample at a constant rate of 5 mm/min until the first insulating layer or the second insulating layer breaks, or until the load of the first insulating layer or the second insulating layer decreases by 10%.

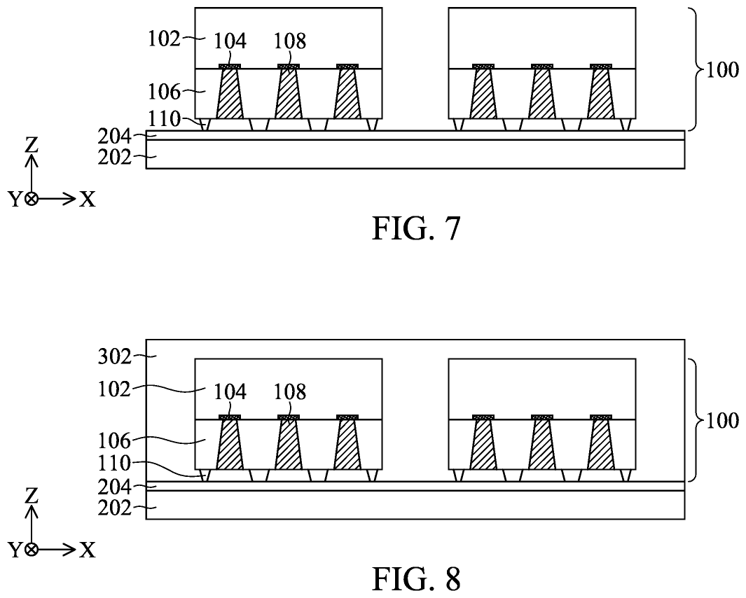

Next, FIGS. 7-11 illustrate cross-sectional views of an electronic device at various intermediate stages of its manufacturing process according to some embodiments of the disclosure. Referring to FIG. 7, according to some embodiments, the electronic units 100 in FIG. 6 are transferred to a carrier substrate 202. Specifically, the electronic units 100 are inverted and disposed on the carrier substrate 202. In some embodiments, a release layer 204 may be disposed on the carrier substrate 202 so that the electronic units 100 may be temporarily attached to the carrier substrate 202 for further processing. According to some embodiments, the carrier substrate 202 may include quartz, glass, stainless steel, sapphire, another suitable material, or combination thereof, but the disclosure is not limited thereto.

According to some embodiments, the release layer 204 may be a thermal-type release adhesive material or an optical-type release adhesive material. After completing the subsequent molding process of the electronic units 100, the release layer 204 may be irradiated with laser (when using an optical-type release material) or may be heated (when using a thermal-type release material). Therefore, the release layer 204 loses the adhesive property and detaches from the carrier substrate 202. In some embodiments, the optical-type release material may include polyimide or other suitable materials, but the disclosure is not limited thereto. In some embodiments, the thermal-type release material may include, but is not limited to, resin, epoxy, acrylate resin, polyurethane (PU), polyethylene terephthalate (PET)-like polymer materials, or other suitable materials.

Next, referring to FIG. 8, in the cross-section view, a molding process is performed on the structure in FIG. 7 to form a protective layer 302 surrounding the electronic units 100. According to some embodiments, the protective layer 302 may be formed on the carrier substrate 202. In one embodiment, when the release layer 204 is disposed on the carrier substrate 202, the protective layer 302 may be further formed on the release layer 204. It should be noted that “A surrounds B” as used herein means that A at least surrounds three faces of B, and that “A surrounds B and C” as used herein means that A at least surrounds three faces of B and three faces of C, and that A is between B and C.

As shown in FIG. 8, multiple electronic units 100 may be disposed on the carrier substrate 202. Accordingly, the protective layer 302 may surround these electronic units 100, suggesting that the protective layer 302 is also between neighboring electronic units 100. According to some embodiments, the material of the protective layer 302 may include an organic insulating material or an inorganic insulating material to isolate ambient vapor and oxygen. For example, the organic insulating material may include, but is not limited to, epoxy or siloxane resin. For example, the inorganic insulating material may include, but is not limited to, silicon nitride, silicon oxide, silicon oxynitride, silicon carbide, aluminum oxide or a combination thereof.

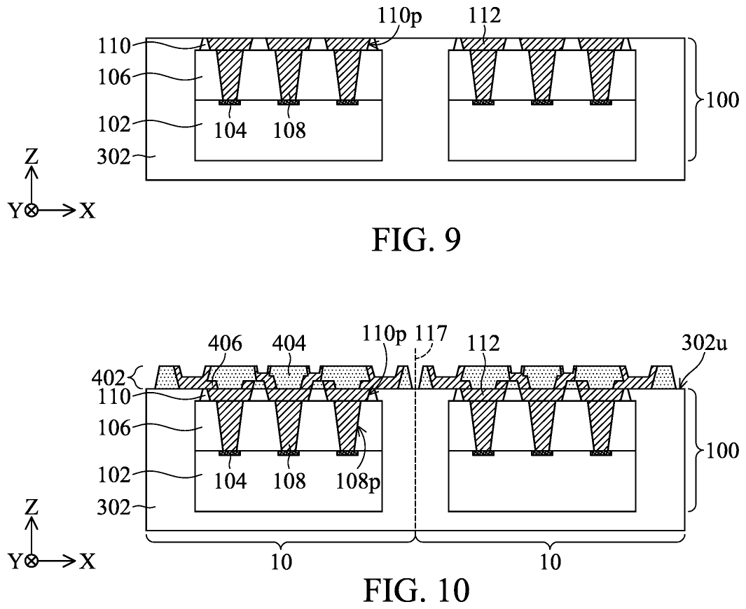

Subsequently, referring to FIG. 9, according to some embodiments, the carrier substrate 202 and the release layer 204 are removed. As described above, the release layer 204 may lose adhesion using different methods according to the material of the release layer 204. For example, the release layer 204 is subjected to heat (e.g., when the release layer 204 includes a thermal-type release material) or irradiated with laser (e.g., when the release layer 204 includes an optical-type release material). Once the release layer 204 loses adhesion, the electronic units 100 and the protective layer 302 may be detached from the carrier substrate 202.

In some embodiments, after removing the carrier substrate 202 and the release layer 204, the openings 110p of the second insulating layer 110 may be filled with a second metal layer 112. Specifically, according to some embodiments, the material of the second metal layer 112 may be formed to overfill the openings 110p, and then the second metal layer 112 is planarized by a suitable planarization process, such as mechanical polishing, chemical mechanical polishing, laser grinding, or a suitable planarization process. Therefore, after the planarization process, the upper surfaces of the second insulating layer 110, the second metal layer 112, and the protective layer 302 may be substantially level. The method and material for forming the second metal layer 112 may be similar to or the same as those of the first metal layer 108, which are not repeated herein.

Next, referring to FIG. 10, a circuit layer 402 is formed on the electronic unit 100 to complete the electronic device 10. The circuit layer 402 is electrically connected to the electronic unit 100. According to some embodiments, as shown in FIG. 10, the circuit layer 402 may extend horizontally from the upper surface of the electronic unit 100 to the upper surface 302u of the protective layer 302. More specifically, the circuit layer 402 may extend horizontally from the upper surface of the electronic unit 100 to the upper surface 302u of the protective layer 302 along the direction parallel to the main surface of the electronic unit 100 (e.g., the X direction in FIG. 10). In some embodiments, the thickness of the circuit layer 402 may be between about 2.0 μm and about 10 μm, such as about 6.0 μm.

In some embodiments, the circuit layer 402 may be formed by alternately stacking multiple insulating layers 404 and multiple metal layers 406. In the circuit layer 402, the metal layer 406 may include multiple conductive layer and multiple conductive vias although they are not explicitly shown in FIG. 10. The conductor layers can be electrically connected to each other through the conductive vias, and the numbers of the conductor layers and the conductive vias in the metal layer 406 can be selected according to product requirements. The material and method for forming the metal layer 406 may be similar to or the same as those of the first metal layer 108, which are not repeated herein. Similarly, the material and method for forming the insulating layer 404 may be similar to or the same as those of the second insulating layer 110, which are not repeated herein. In some embodiments, the circuit layer 402 may be, for example, a redistribution (RDL) layer. By disposing the circuit layer 402, the fan-out area of the circuit in the electronic device may be further increased.

Moreover, in some embodiments, as shown in FIG. 10, the circuit layer 402 may expose a portion of the upper surface 302u of the protective layer 302. Specifically, two neighboring electronic devices 10 are illustrated in FIG. 10, and a pre-determined dicing lane 117 is present between the electronic devices 10. The circuit layer 402 may expose the upper surface 302u of the protective layer 302 that is at the dicing lane 117. In addition to the upper surface 302u of the protective layer 302 that is at the dicing lane 117, the circuit layer 402 may further expose the upper surface of the protective layer 302 on the outside of each electronic device 10. It should be appreciated that the outside refers to another side that is opposite the side on which the dicing lane 117 is located. In one embodiment, in the top-view of each electronic device 10 (not shown), the exposed upper surface 302u of the protective layer 302 may surround the circuit layer 402. That is, the exposed upper surface 302u of the protective layer 302 has a ring structure surrounding the circuit layer 402.

In addition, according to some embodiments, the circuit layer 402 may be electrically connected to the conductive pads 104 of the electronic unit 100 through the openings 106p of the first insulating layer 106 and the openings 110p of the second insulating layer 110. More specifically, in one embodiment, the circuit layer 402 may be electrically connected to the conductive pads 104 of the electronic unit 100 through the first metal layer 108 in the openings 106p and the second metal layer 112 in the openings 110p. In addition, the chip unit 102 in the electronic unit 100 may be electrically connected to circuit layer 402 through the conductive pads 104.

According to the embodiments of the disclosure, the electronic unit 100 in the electronic device 10 may have a thicker first insulating layer 106 and a thinner second insulating layer 110. The first insulating layer 106 with a greater thickness can protect the chip unit 102 from being affected by the ambient factors during the manufacturing process, thereby avoiding impaired performance of the chip unit 102 and increasing reliability of the electronic device 10. On the other hand, the second insulating layer 110 with a lesser thickness may increase the layout area of the circuit in the electronic device such that the electrical connection between the electronic unit 100 and other subsequently formed electronic units may extend horizontally from the electronic unit 100 toward the outside of the electronic unit 100. Therefore, the electronic device 10 can have a larger circuit fan-out area, thereby enhancing the overall electrical property of the electronic device 10.

Referring again to FIG. 10, in some embodiments, a dicing process is performed to separate the neighboring electronic devices 10. In particular, according to some embodiments, a suitable dicing process is performed at the dicing lane 117 in FIG. 10 to separate the neighboring electronic devices 10 from each other. For example, the suitable dicing process may include etching, cutting wheel dicing, laser dicing, another suitable dicing technique, or a combination thereof.

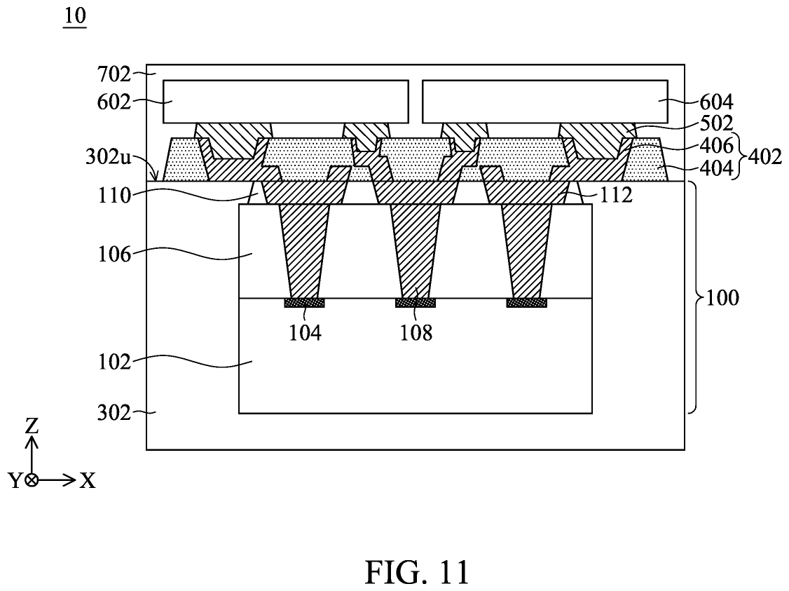

Next, referring to FIG. 11, in some embodiments, after the dicing process, further package process may be performed, such as a die bonding process. For example, bonding pads 502 may be formed on the circuit layer 402. Specifically, in some embodiments, the bonding pads 502 are formed on the metal layer 406 of the circuit layer 402 to electrically connect the circuit layer 402 and electronic units that are disposed subsequently. The number of the bonding pads 502 may be disposed according to actual need. The material of the bonding pads 502 may be a metal, such as Nickel (Ni), Copper (Cu), Gold (Au), Tin (Sn), or Aluminum (Al), but the disclosure is not limited thereto.

Next, at least one electronic unit is bonded on the bonding pads 502. For example, in some embodiments, as shown in FIG. 11, electronic units 602 and 604 are bonded on the bonding pads 502. It should be understood that although two additional electronic units 602 and 604 are illustrated to be disposed on the bonding pads 502 in the electronic device 10 in FIG. 11, the disclosure is not limited thereto. In other embodiments, more or fewer electronic units may be disposed according to product requirements. The example of the electronic units 602 and 604 may include a low noise amplifier (LNA), a low-loss filter, a power amplifier, a baseband circuit, a power management integrated circuit (PMIC), a memory, a micro electro mechanical system (MEMS) device, an integrated circuit (IC), another suitable active or passive component, or a combination thereof, but the disclosure is not limited thereto.

After completing the electronic device 10 shown in FIG. 11, additional package processes may be further performed. In particular, according to some embodiments, an additional protective layer 702 may be formed surrounding the electronic unit 100, the circuit layer 402, the bonding pads 502, and the electronic units 602 and 604, thereby resulting in a complete package structure. The material used for the additional protective layer 702 may be the same as that of the protective layer 302, which is not repeated herein. The formation of the additional protective layer 702 on the structure shown in FIG. 11 may be further prevent ambient vapor and oxygen from penetrating into the electronic device 10 and thus from affecting the performance of the electronic device 10. The additional protective layer 702 is in contact with the exposed upper surface 302u of the protective layer 302. This enhances adhesion, and thus increases reliability of the electronic device 10, but the disclosure is not limited thereto.

In summary, according to some embodiments, the electronic unit in the electronic device has a first insulating layer and a second insulating layer. The first insulating layer with a greater thickness can provide stable protection for the chip unit, thereby avoiding impaired performance of the chip unit and increasing reliability of the electronic device. On the other hand, the second insulating layer with a lesser thickness may increase the circuit layout area in the electronic device, thereby enhancing the overall electrical property of the electronic device. Consequently, adopting the manufacturing method of the embodiments of the disclosure can both increase reliability of the electronic device and achieve desired circuit fan-out result.

Although some embodiments of the disclosure and their advantages have been described in detail, it should be understood that various changes, substitutions and alterations can be made herein without departing from the spirit and scope of the disclosure. The features between embodiments of the disclosure may be arbitrarily applied to one another without departing from the spirit and scope of the disclosure. Moreover, the scope of the present application is not intended to be limited to the particular embodiments of the process, machine, manufacture, composition of matter, means, methods and steps described in the specification. As a person having ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. The scope of the present disclosure shall be defined by the appended claims. Any one of embodiments or claims of the present disclosure do not have to achieve all the aspects, advantages or features disclosed in the disclosure.

What is claimed is:

1. An electronic device, comprising:
an electronic unit comprising:
a chip unit;
a first insulating layer disposed on the chip unit; and
a second insulating layer disposed on the first insulating layer, wherein the second insulating layer has a first side that overlaps the chip unit along a normal direction of the electronic unit;
a protective layer surrounding the electronic unit; and
a circuit layer electrically connected to the electronic unit.

2. The electronic device of claim 1, wherein the first insulating layer has a second side, and the chip unit has a third side aligned with the second side.

3. The electronic device of claim 2, wherein the second side of the first insulating layer has a first roughness, and the third side of the chip unit has a second roughness, and wherein the first roughness is greater than the second roughness.

4. The electronic device of claim 1, wherein the second insulating layer exposes a portion of an upper surface of the first insulating layer.

5. The electronic device of claim 1, wherein an angle between the first side and a lower surface of the second insulating layer is greater than or equal to 45° and less than 90°.

6. The electronic device of claim 1, wherein the first insulating layer has a first thickness, and the second insulating layer has a second thickness, and wherein the first thickness is greater than the second thickness.

7. The electronic device of claim 1, wherein:
the first insulating layer has first openings and the second insulating layer has second openings;
one of the first openings has a first sidewall with a third roughness; and
one of the second openings has a second sidewall with a fourth roughness that is less than the third roughness.

8. The electronic device of claim 7, wherein the first sidewall has a concave shape.

9. The electronic device of claim 7, wherein the electronic unit further comprises conductive pads, and wherein the circuit layer is electrically connected to the conductive pads of the electronic unit through the first openings and the second openings.

10. A method for manufacturing an electronic device, comprising:
providing a chip unit;
forming a first insulating layer on the chip unit;
forming a second insulating layer on the first insulating layer; and
performing a dicing process to form an electronic unit, wherein the second insulating layer has a first side that overlaps the electronic unit along a normal direction of the electronic unit after the dicing process.

11. The method of claim 10, wherein the first insulating layer has a second side, and the chip unit has a third side aligned with the second side after the dicing process.

12. The method of claim 11, wherein the second side of the first insulating layer has a first roughness, and the third side of the chip unit has a second roughness, and wherein the first roughness is greater than the second roughness.

13. The method of claim 10, wherein the first insulating layer has a first thickness, and the second insulating layer has a second thickness, and wherein the first thickness is greater than the second thickness.

14. The method of claim 10, further comprising forming first openings in the first insulating layer and forming second openings in the second insulating layer, wherein one of the first openings has a first sidewall with a third roughness, and one of the second openings has a second sidewall with a fourth roughness that is less than the third roughness.

15. The method of claim 14, wherein the step of forming the first opening comprises using a laser drilling process to form the first openings, and wherein the step of forming the second openings comprises using a photolithography process to form the second openings.

16. The method of claim 15, wherein the second insulating layer exposes a portion of an upper surface of the first insulating layer after the photolithography process.

17. The method of claim 14, wherein the first sidewall has a concave shape.

18. The method of claim 10, further comprising transferring the electronic unit to a carrier substrate and forming a protective layer surrounding the electronic unit.

19. The method of claim 18, further comprising forming a circuit layer on the electronic unit, wherein the circuit layer is electrically connected to the electronic unit.

20. The method of claim 19, wherein the circuit layer extends horizontally from an upper surface of the electronic unit to an upper surface of the protective layer.
